(19) United States
(12) Patent Application Publication
(10) Pub. No.: US 2025/0059389 A1
(43) Pub. Date: Feb. 20, 2025

(54) SURFACE TREATMENT AGENT, SURFACE TREATMENT METHOD, AND AREA-SELECTIVE FILM FORMING METHOD ON SUBSTRATE SURFACE

(71) Applicant: TOKYO OHKA KOGYO CO., LTD., Kawasaki-shi (JP)

(72) Inventors: Jun IIOKA, Kawasaki-shi (JP); Kenji SEKI, Kawasaki-shi (JP); Taiji NAKAMURA, Kawasaki-shi (JP)

(21) Appl. No.: 18/940,071

(22) Filed: Nov. 7, 2024

Related U.S. Application Data
(62) Division of application No. 17/457,329, filed on Dec. 2, 2021.

(30) Foreign Application Priority Data
Dec. 21, 2020 (JP) 2020-211823

(51) Int. Cl. C09D 7/63; C23C 16/02; C23C 16/455

(52) U.S. Cl. CPC C09D 7/63; C23C 16/0272; C23C 16/45525

(57) ABSTRACT

A surface treatment agent including a compound (P) represented by R¹—P(═O)(OR²)(OR³) in which R¹ is an alkyl group, an alkoxy group, a fluorinated alkyl group, or an aromatic hydrocarbon group which may have a substituent, and R² and R³ are each independently a hydrogen atom, an alkyl group, a fluorinated alkyl group, or an aromatic hydrocarbon group which may have a substituent; a compound (S) represented by R—SH . . . in which R is an alkyl group having 3 or more carbon atoms, a fluorinated alkyl group having 3 or more carbon atoms, or an aromatic hydrocarbon group which may have a substituent; and a solvent.

### RELATED APPLICATIONS

This application is a divisional of U.S. patent application Ser. No. 17/457,329, filed Dec. 2, 2021, which claims priority to Japanese Patent Application No. 2020-211823, filed Dec. 21, 2020, the entire content of which is incorporated herein by reference.

### BACKGROUND OF THE INVENTION

### Field of the Invention

The present invention relates to a surface treatment agent, a surface treatment method, and a method for area-selectively forming a film on a substrate surface.

### Related Art

Recently, the tendency of high integration and downsizing of semiconductor devices is increasing. Along with this, there has been progress in downsizing a patterned organic film serving as a mask and a patterned inorganic film produced by an etching process. Therefore, there is a demand for film thickness control at an atomic layer level of an organic film or an inorganic film formed on a semiconductor substrate.

As a method of forming a thin film at an atomic layer level on a substrate, an atomic layer deposition method (ALD (Atomic Layer Deposition) method; hereinafter, simply referred to as “ALD method”) is known. The ALD method is known for higher step coverage performance and film thickness controllability compared with common CVD (Chemical Vapor Deposition) method.

The ALD method is a thin film forming technique in which a thin film having a desired thickness is formed by repeating alternate supply of two types of gases multiple times to form a thin film in an atomic layer unit on the substrate, the gases each containing an element constituting the film to be formed as a main component.

The ALD method utilizes a self-controlling function (self-limiting function) of growth in which a component of a raw material gas is adsorbed on a substrate surface only in an extent that one or several atomic layers are formed, while the raw material gas is supplied, whereas an extra raw material gas does not contribute to growth.

For example, when forming an Al₂O₃ film on the substrate, an oxidizing gas comprising TMA (trimethyl aluminum) and oxygen is used. Further, when forming a nitride film on the substrate, a nitriding gas is used instead of the oxidizing gas.

Recently, a method of area-selectively forming a film on a substrate surface using the ALD method has been attempted (see Patent Document 1 and Non-Patent Document 1).

Accordingly, there has been a demand for a substrate having a surface which is area-selectively modified so as to be suitably applied to area-selective film formation on a substrate by the ALD method. In addition, such a substrate is also required to have a surface which is resistant to chemical vapors, oxidizing gases, and nitriding gases of CVD/ALD precursors.

Patent Document 1: Japanese Unexamined Patent Application (Translation of PCT Application), Publication No. 2003-508897

Non-Patent Document 1: J. Phys. Chem. C 2014, 118, 10957-10962

### SUMMARY OF THE INVENTION

In view of the above circumstances, it is an object of the present invention to provide a surface treatment agent which can provide a substrate surface having a plurality of areas with modification, such as provision of hydrophobicity, the surface treatment agent being able to impart different modification degrees to the plurality of areas depending on the material of each area, and to provide the substrate surface with resistance to chemical liquids and chemical vapors; a method for treating a surface of a substrate by using the surface treatment agent; and a method for area-selectively forming a film on a surface of a substrate, including the above-described method for treating a surface of a substrate.

A first aspect of the present invention relates to a surface treatment agent, including:
compound (P) represented by the following general formula (P-1):

R¹—P(═O)(OR²)(OR³) (P-1)

[In the formula, R¹ is an alkyl group, an alkoxy group, a fluorinated alkyl group, or an aromatic hydrocarbon group which may have a substituent, and R² and R³ are each independently a hydrogen atom, an alkyl group, a fluorinated alkyl group, or an aromatic hydrocarbon group which may have a substituent];
a compound (S) represented by the following formula (S-1):

R—SH (S-1)

[In the formula, R is an alkyl group having 3 or more carbon atoms, a fluorinated alkyl group having 3 or more carbon atoms, or an aromatic hydrocarbon group which may have a substituent]; and
a solvent.

A second aspect of the present invention relates to a method for surface treating a surface of a substrate, the method including:
exposing the surface to the surface treatment agent as described in the first aspect,
in which the surface includes two or more areas;
in the two or more areas, materials of adjacent areas are different from each other; and
the adjacent areas in the two or more areas have different contact angles due to reaction of the compound (P) and the compound (S) with the two or more areas.

A third aspect of the present invention relates to a method for area-selectively forming a film on a surface of a substrate, the method including:
treating the surface of the substrate by the method for surface treating as described in the second aspect, and
forming a film on the surface of the substrate subjected to the surface treatment by an atomic layer deposition method, in which a deposited amount of a material for the film is selectively varied in an area-selective manner.

According to the present invention, it is possible to provide a surface treatment agent which can provide a substrate surface having a plurality of areas with modification, such as provision of hydrophobicity, the surface treatment agent being able to impart different modification degrees to the plurality of areas depending on the material of each area, and to provide the substrate surface with resistance to chemical liquids and chemical vapors; and a method for area-selectively forming a film on a surface of the substrate, including the aforementioned method for surface treating a substrate.

### DETAILED DESCRIPTION OF THE INVENTION

### Surface Treatment Agent

The surface treatment agent contains a compound (P) represented by the following general formula (P-1), a compound (S) represented by the following general formula (S-1), and a solvent. Further, the surface treatment agent may contain other components than the compound (P), the compound (S), and the solvent as long as the desired effect is obtained. Hereinafter, essential or optional components that the surface treatment agent may include will be described.

### Compound (P)

The surface treatment agent includes a compound (P) represented by the following general formula (P-1):

R¹—P(═O)(OR²)(OR³) (P-1)

[In the formula, R¹ is an alkyl group, an alkoxy group, a fluorinated alkyl group, or an aromatic hydrocarbon group which may have a substituent, and R² and R³ are each independently a hydrogen atom, an alkyl group, a fluorinated alkyl group, or an aromatic hydrocarbon group which may have a substituent.]

In the compound (P) represented by formula (P-1), a linear or branched alkyl group having 8 or more carbon atoms is preferred as the alkyl group of R¹, and a linear or branched alkyl group having 12 or more carbon atoms is more preferred.

Suitable examples of alkyl groups as R¹ include: an octyl group, a nonyl group, a decyl group, an undecyl group, a dodecyl group, a tridecyl group, an isotridecyl group, a tetradecyl group, a pentadecyl group, a hexadecyl group, an isohexadecyl group, a heptadecyl group, an octadecyl group, a nonadecyl group, an icosyl group, a henicosyl group, and a docosyl group, as well as alkyl groups which are structural isomers of these alkyl groups.

In the compound (P) represented by formula (P-1), as the alkoxy group of R¹, a linear or branched alkoxy group having 8 or more carbon atoms is preferred, and a linear or branched alkoxy group having 12 or more carbon atoms is more preferred.

Suitable examples of alkoxy groups as R¹ include: an octyloxy group, a nonyloxy group, a decyloxy group, an undecyloxy group, a dodecyloxy group, a tridecyloxy group, an isotridecyloxy group, a tetradecyloxy group, a pentadecyloxy group, a hexadecyloxy group, an isohexadecyloxy group, a heptadecyloxy group, an octadecyloxy group, a nonadecyloxy group, an icosyloxy group, a henicosyloxy group, and a docosyloxy group, as well as alkoxy groups which are structural isomers of these alkoxy groups.

In the compound (P) represented by formula (P-1), as the fluorinated alkyl group of R¹, a linear or branched fluorinated alkyl group having 8 or more carbon atoms is preferred, and a linear or branched fluorinated alkyl group having 12 or more carbon atoms is more preferred.

Suitable examples of fluorinated alkyl groups as R¹ include a group in which some or all of the hydrogen atoms of the alkyl group of R¹ exemplified above are substituted with fluorine atoms.

In the compound (P) represented by the formula (P-1), examples of the aromatic hydrocarbon group which may have a substituent of R¹ include: a phenyl group, a naphthyl group, an anthryl group, a p-methylphenyl group, a p-tert-butylphenyl group, a p-adamantylphenyl group, a tolyl group, a xylyl group, a cumenyl group, a mesityl group, a biphenyl group, a phenanthryl group, a 2,6-diethylphenyl group, and a 2-methyl -6-ethylphenyl group.

In the compound (P) represented by formula (P-1), the upper limit of the number of carbon atoms possessed by the above-described substituents of RI is not particularly limited, but is, for example, 45 or less.

In the compound (P) represented by formula (P-1), a linear or branched alkyl group having 8 or more carbon atoms is preferred, as the alkyl group of R² and R³.

Suitable examples of alkyl groups as R² and R³ include: an octyl group, a nonyl group, a decyl group, an undecyl group, a dodecyl group, a tridecyl group, an isotridecyl group, a tetradecyl group, a pentadecyl group, a hexadecyl group, an isohexadecyl group, a heptadecyl group, an octadecyl group, a nonadecyl group, an icosyl group, a henicosyl group, and a docosyl group, as well as alkyl groups which are structural isomers of these alkyl groups.

In the compound (P) represented by formula (P-1), a linear or branched fluorinated alkyl group having 8 or more carbon atoms is preferred as the fluorinated alkyl group of R² and R³.

Suitable examples of the fluorinated alkyl group as R² and R³ include groups in which some or all of the hydrogen atoms of the alkyl groups of R² and R³ exemplified above are substituted with fluorine atoms.

In the compound (P) represented by the formula (P-1), examples of the aromatic hydrocarbon group which may have a substituent of R² and R³ include: a phenyl group, a naphthyl group, an anthryl group, a p-methylphenyl group, a p-tert-butylphenyl group, a p-adamantylphenyl group, a tolyl group, a xylyl group, a cumenyl group, a mesityl group, a biphenyl group, a phenanthryl group, a 2, 6-diethylphenyl group, and a 2-methyl-6-ethylphenyl group.

Among them, as R² and R³, hydrogen atoms are preferred.

One type of the compound (P) may be used alone, or two or more types thereof may be used.

The content of the compound (P) is preferably 0.001% by mass or more and 5% by mass or less, more preferably 0.005% by mass or more and 4% by mass or less, more preferably 0.01% by mass or more and 3% by mass or less, and most preferably 0.03% by mass or more and 3% by mass or less, with respect to the total mass of the surface treatment agent. In the method for treating a surface including two or more areas, in which adjacent areas are made of materials different from each other, when the content of the compound (P) is within the above preferable range and when at least one area contains a metal surface, the compound (P) easily adsorbs to the area containing a metal surface, whereby selectivity of the surface treatment agent to the area containing a metal surface is easily improved.

### Compound (S)

The surface treatment agent includes a compound (S) represented by the following general formula (S-1), from the viewpoint of improving resistance to chemical liquids and chemical vapors containing an acid or a base.

R—SH (S-1)

[In the formula, R is an alkyl group having 3 or more carbon atoms, a fluorinated alkyl group having 3 or more carbon atoms, or an aromatic hydrocarbon group which may have a substituent.]

In the compound (S) represented by formula (S-1), as the alkyl group of R, a linear or branched alkyl group having 7 or more carbon atoms is preferred from the viewpoint of improving an anticorrosive effect, a linear or branched alkyl group having 10 or more carbon atoms is more preferred, and a linear or branched alkyl group having 15 or more carbon atoms is most preferred.

Suitable examples of the alkyl group as R include: a propyl group, a butyl group, a pentyl group, a hexyl group, a heptyl group, an octyl group, a nonyl group, a decyl group, an undecyl group, a dodecyl group, a tridecyl group, an isotridecyl group, a tetradecyl group, a pentadecyl group, a hexadecyl group, an isohexadecyl group, a heptadecyl group, an octadecyl group, a nonadecyl group, an icosyl group, a henicosyl group, and a docosyl group, as well as alkyl groups which are structural isomers of these alkyl groups.

In the compound (S) represented by formula (S-1), as the fluorinated alkyl group of R, a linear or branched fluorinated alkyl group having 7 or more carbon atoms is preferred from the viewpoint of improving an anticorrosive effect, a linear or branched fluorinated alkyl group having 10 or more carbon atoms is more preferred, and a linear or branched fluorinated alkyl group having 15 or more carbon atoms is most preferred.

Suitable examples of the fluorinated alkyl group as R include a group in which some or all of the hydrogen atoms of the alkyl group of R exemplified above are substituted with fluorine atoms.

In the compound (S) represented by the formula (S-1), examples of the aromatic hydrocarbon group which may have a substituent of R include: a phenyl group, a naphthyl group, an anthryl group, a p-methylphenyl group, a p-tert-butylphenyl group, a p-adamantylphenyl group, a tolyl group, a xylyl group, a cumenyl group, a mesityl group, a biphenyl group, a phenanthryl group, a 2, 6-diethylphenyl group, and a 2-methyl -6-ethylphenyl group.

In the compound (S) represented by formula (S-1), the upper limit of the number of carbon atoms possessed by the above-described substituent of R is not particularly limited, but is, for example, 45 or less.

One type of the compound (S) may be used alone, or two or more types thereof may be used. The content of the compound(s) is preferably 0.05% by mass or more and 5% by mass or less, more preferably 0.1% by mass or more and 48 by mass or less, most preferably 0.2% by mass or more and 3% by mass or less, with respect to the total mass of the surface treatment agent, from the viewpoint of improving resistance against acids and bases.

### Solvent

The surface treatment agent includes a solvent. When the surface treatment agent contains a solvent, surface treatment of the substrate by an immersion method, a spin coating method, or the like is easily performed.

Examples of the solvent include sulfoxides, sulfones, amides, lactams, imidazolidinones, dialkyl glycol ethers, monoalcohol-based solvents, (poly)alkylene glycol monoalkyl ethers, (poly)alkylene glycol monoalkyl ether acetates, other ethers, ketones, other esters, lactones, linear, branched, or cyclic aliphatic hydrocarbons, aromatic hydrocarbons, terpenes, and the like.

As the sulfoxides, dimethyl sulfoxide may be mentioned.

Examples of the sulfones include dimethylsulfone, diethylsulfone, bis(2-hydroxyethyl) sulfone, and tetramethylene sulfone.

Examples of the amides include N,N-dimethylformamide, N-methylformamide, N,N-dimethylacetamide, N-methylacetamide, and N,N-diethylacetamide.

Examples of the lactams include N-methyl-2-pyrrolidone, N-ethyl-2-pyrrolidone, N-propyl-2-pyrrolidone, N-hydroxymethyl -2-pyrrolidone, and N-hydroxyethyl-2-pyrrolidone.

Examples of the imidazolidinones include 1,3-dimethyl-2-imidazolidinone, 1,3-diethyl-2-imidazolidinone, and 1,3-diisopropyl-2-imidazolidinone.

Examples of the dialkyl glycol ethers include dimethyl glycol, dimethyl diglycol, dimethyl triglycol, methyl ethyl diglycol, diethyl glycol, and triethylene glycol butyl methyl ether.

Examples of the monoalcohol-based solvent include: methanol, ethanol, n-propanol, isopropanol, n-butanol, isobutanol, sec-butanol, tert-butanol, n-pentanol, isopentanol, 2-methylbutanol, sec-pentanol, tert-pentanol, 3-methoxybutanol, 3-methyl-3-methoxybutanol, n-hexanol, 2-methylpentanol, sec-hexanol, 2-ethylbutanol, sec-heptanol, 3-heptanol, 1-octanol, 2-ethylhexanol, sec-octanol, n-nonyl alcohol, 2,6-dimethyl-4-heptanol, n-decanol, sec-undecyl alcohol, trimethylnonyl alcohol, sec-tetradecyl alcohol, sec-heptadecyl alcohol, phenol, cyclohexanol, methylcyclohexanol, 3,3,5-trimethylcyclohexanol, benzyl alcohol, phenylmethylcarbinol, diacetone alcohol, and cresol.

Examples of the (poly)alkylene glycol monoalkyl ethers include: ethylene glycol monomethyl ether, ethylene glycol monoethyl ether, ethylene glycol mono-n-propyl ether, ethylene glycol mono-n-butyl ether, diethylene glycol monomethyl ether, diethylene glycol monoethyl ether, diethylene glycol mono-n-propyl ether, diethylene glycol mono-n-butyl ether, triethylene glycol monomethyl ether, triethylene glycol monoethyl ether, propylene glycol monomethyl ether, propylene glycol monoethyl ether, propylene glycol mono-n-propyl ether, propylene glycol mono-n-butyl ether, dipropylene glycol monomethyl ether, dipropylene glycol monoethyl ether, dipropylene glycol mono-n-propyl ether, dipropylene glycol mono-n-butyl ether, tripropylene glycol monomethyl ether, and tripropylene glycol monoethyl ether.

Examples of the (poly)alkylene glycol monoalkyl ether acetates include: ethylene glycol monomethyl ether acetate, ethylene glycol monoethyl ether acetate, ethylene glycol monobutyl ether acetate, diethylene glycol monomethyl ether acetate, diethylene glycol monoethyl ether acetate, propylene glycol monomethyl ether acetate, and propylene glycol monoethyl ether acetate.

Examples of other ethers include: dimethyl ether, diethyl ether, methyl ethyl ether, dipropyl ether, diisopropyl ether, dibutyl ether, diisoamyl ether, diethylene glycol dimethyl ether, diethylene glycol methyl ethyl ether, diethylene glycol diethyl ether, tetraethylene glycol dimethyl ether, and tetrahydrofuran.

Examples of the ketones include methyl ethyl ketone, cyclohexanone, 2-heptanone, and 3-heptanone.

Other esters include: alkyl lactates such as methyl 2-hydroxypropionate, ethyl 2-hydroxypropionate, etc.; ethyl 2-hydroxy-2-methylpropionate, methyl 3-methoxypropionate, ethyl 3-methoxypropionate, methyl 3-ethoxy propionate, ethyl 3-ethoxy propionate, ethyl ethoxyacetate, ethyl hydroxyacetate, methyl 2-hydroxy-3-methylbutanoate, 3-methoxybutyl acetate, 3-methyl-3-methoxy-1-butyl acetate, 3-methyl-3-methoxybutyl propionate, ethyl acetate, n-propyl acetate, isopropyl acetate, n-butyl acetate, isobutyl acetate, n-pentyl acetate, n-hexyl acetate, n-heptyl acetate, n-octyl acetate, n-pentyl formate, isopentyl acetate, n-butyl propionate, ethyl butyrate, n-propyl butyrate, isopropyl butyrate, n-butyl butyrate, methyl n-octanoate, methyl decanoate, methyl pyruvate, ethyl pyruvate, n-propyl pyruvate, methyl acetoacetate, ethyl acetoacetate, ethyl 2-oxobutanoate, dimethyl adipate, and propylene glycol diacetate.

Examples of the lactones include propiolactone, γ-butyrolactone, and 6-pentyrolactone.

Examples of the linear, branched, or cyclic aliphatic hydrocarbons include: n-hexane, n-heptane, n-octane, n-nonane, methyl octane, n-decane, n-undecane, n-dodecane, 2,2,4,6,6-pentamethylheptane, 2,2,4,4,6,8,8-heptamethylnonane, cyclohexane, and methylcyclohexane.

Examples of the aromatic hydrocarbon include benzene, toluene, xylene, 1,3,5-trimethylbenzene, and naphthalene.

Examples of the terpenes include p-menthane, diphenylmenthane, limonene, terpinene, bornane, norbornane, and pinane.

Among these solvents, 3-methyl-3-methoxy-1-butyl acetate, ethyl acetate, propylene glycol monomethyl ether acetate, propylene glycol monomethyl ether, diethylene glycol monomethyl ether, 1-octanol, and methyl ethyl ketone are preferred, and propylene glycol monomethyl ether and 1-octanol are more preferred.

### Other Ingredients

The surface treatment agent may contain components (hereinafter, also referred to as “other components”) other than the compound (P), the compound (S), and the solvent, as long as the effect of the present invention is not impaired. Examples of the other components include an antioxidant, an ultraviolet absorber, a viscosity adjusting agent, a defoaming agent, and a pH adjusting agent.

The surface treatment agent is obtained by mixing the above-described compound (P), the compound (S), the solvent, and, other components as required by a known method.

It is preferable that the surface treatment agent is used for treating a surface containing two or more areas, in which adjacent areas are made of materials different from each other. In such a case, it is preferred that at least one area of the two or more areas has a surface made of metal, and the metal is more preferably copper, cobalt or ruthenium.

### Surface Treatment Method

The surface treatment method is a surface treatment method for treating a surface of a substrate, including exposing the surface to the surface treatment agent of the present invention.

In the surface treatment method, the surface includes two or more areas, and adjacent areas of the two or more areas are different from each other in the material. Reaction of the compound (P) and the compound (S) with the above-described two or more areas makes contact angles different from each other between the adjacent areas among the two or more areas.

In the present embodiment, as a “substrate” to be subjected to the surface treatment, a substrate used for manufacturing semiconductor devices is exemplified. Examples of such a substrate include a silicon (Si) substrate, a silicon nitride (SiN) substrate, a silicon oxidized film (Ox) substrate, a tungsten (W) substrate, a cobalt (Co) substrate, a titanium nitride (TiN) substrate, a tantalum nitride (TaN) substrate, a germanium (Ge) substrate, a silicon germanium (SiGe) substrate, an aluminum (Al) substrate, a nickel (Ni) substrate, a ruthenium (Ru) substrate, a copper (Cu) substrate, and the like.

The “surface of a substrate” includes a surface of a substrate itself, as well as a surface of a patterned inorganic layer and a patterned organic layer provided on the substrate, and a surface of an unpatterned inorganic layer or an unpatterned organic layer provided on the substrate.

As the patterned inorganic layer provided on the substrate, a patterned inorganic layer formed by making an etching mask on a surface of an inorganic layer present on a substrate by a photoresist method and then performing an etching treatment is exemplified. Examples of the inorganic layer include, in addition to the substrate itself, an oxidized film of an element constituting the substrate, a film or a layer of an inorganic material such as SiN, Ox, W, Co, TiN, TaN, Ge, SiGe, Al, Al₂O₃, Ni, Ru, Cu, etc. formed on the surface of the substrate, and the like.

Such a film or layer is not particularly limited, and examples thereof include a film or a layer of an inorganic material formed in the process of manufacturing a semiconductor device.

As the patterned organic layer provided on a substrate, a patterned resin layer or the like formed on the substrate by a photolithography method using a photoresist or the like is exemplified. Such a patterned organic layer can be formed, for example, by forming an organic layer, which is a film of photoresist, on a substrate and exposing the organic layer through a photomask, followed by development. As the organic layer, in addition to the surface of a substrate itself, an organic layer provided on the surface of a laminated film provided on the surface of the substrate or the like may be used. Such an organic layer is not particularly limited, but a film of an organic substance provided for forming an etching mask in the process of manufacturing a semiconductor device can be exemplified.

### Embodiment of Substrate Surface Including Two Areas

In the surface treatment method, a substrate surface includes two or more areas, and materials thereof differ from each other in adjacent areas of the two or more areas.

In the two or more areas, as an area in which the contact angle with water tends to be higher than in the other area, an area containing at least one selected from the group consisting of W, Co, Al, Al₂O₃, Ni, Ru, Cu, TiN, and TaN may be mentioned. In areas where the contact angle with water tends to be larger than in the other area, preferably, the surface free energy is lower. In the two or more areas, as an area in which the contact angle with water tends to be smaller than in the other area, an area containing at least one selected from the group consisting of Si, SiO₂, SiN, Ox, TiN, TaN, Ge, and SiGe may be mentioned. In an area where the contact angle with water tends to be smaller than in the other area, preferably, the surface free energy is higher.

For example, in a case in which an area of one of the two or more areas is defined as a first area and an area adjacent thereto is defined as a second area, materials differ between the first and second areas.

Here, the first area and the second area may or may not be respectively divided into a plurality of areas.

Examples of the first area and the second area include: an embodiment in which a surface of a substrate itself is the first area and a surface of an inorganic layer formed on the surface of the substrate is the second area, and an embodiment in which a surface of a first inorganic layer formed on the surface of the substrate is the first area and a surface of a second inorganic layer formed on the surface of the substrate is the second area. Note that an embodiment in which an organic layer is formed instead of formation of these inorganic layers, and other embodiments may be similarly mentioned.

As the embodiment in which a surface of a substrate itself is the first area and a surface of an inorganic layer formed on the surface of the substrate is the second area, the following embodiment is preferred from the viewpoint of improving difference in the contact angle with water by selectively improving hydrophobicity between the two or more adjacent areas which are made of different materials and which are formed on the substrate surface: a surface of a substrate selected from the group consisting of a Si substrate, a SiN substrate, an Ox substrate, a TiN substrate, a TaN substrate, a Ge substrate and a SiGe substrate is the first area and a surface of an inorganic layer which includes at least one selected from the group consisting of W, Co, Al, Ni, Ru, Cu, TiN and TaN and which is formed on the substrate surface is the second area.

As the embodiment in which a surface of a first inorganic layer formed on the surface of the substrate is the first area and a surface of a second inorganic layer formed on the surface of the substrate is the second area, the following embodiment is preferred from the viewpoint of improving difference in the contact angle with water by selectively improving hydrophobicity between the two or more adjacent areas which are made of different materials and which are formed on the substrate surface: a surface of a first inorganic layer, which is formed, for example, on any substrate such as a Si substrate and which includes at least one selected from the group consisting of SiO₂, SiN, Ox, TiN, TaN, Ge, and SiGe is the first area and a surface of a second inorganic layer, which is formed on the surface of the substrate and which includes at least one selected from the group consisting of W, Co, Al, Ni, Ru, Cu, TiN, and TaN, is the second area.

### Embodiment of Substrate Surface Including Three or More Areas

In a case in which one area of the above two or more areas is the first area, an area adjacent thereto is a second area, and further an area adjacent to the second area is a third area, materials differ between the first area and the second area, and materials differ between the second area and the third area.

Here, when the first area and the third area are adjacent, materials differ between the first area and the third area.

When the first area and the third area are not adjacent, materials may or may not differ between the first area and the third area.

Further, each of the first area, the second area, and the third area may or may not be divided into a plurality of areas.

Examples of the first area, the second area, and the third area include an embodiment in which, for example, a surface of a substrate itself is the first area, a surface of a first inorganic layer formed on the surface of the substrate is the second area, and a surface of a second inorganic layer formed on the surface of the substrate is the third area. Note that an embodiment in which organic layers are formed instead of formation of these inorganic layers or other embodiments can be similarly mentioned. In addition, an embodiment including both an inorganic layer and an organic layer which can be formed by changing only one of the second and third inorganic layers to an organic layer may be mentioned likewise.

From the viewpoint of improving difference in the contact angle with water by selectively improving the hydrophobicity between two or more adjacent areas which are made of different materials and which are formed on the substrate surface, the following embodiment is preferred in which a surface of any substrate itself such as an Si substrate is the first area; a surface of a first inorganic layer which is formed on the surface of the substrate and which contains at least one selected from the group consisting of SiO₂, SiN, Ox, TiN, TaN, Ge, and SiGe is the second area; and a surface of a second inorganic layer which is formed on the surface of the substrate and which contains at least one selected from the group consisting of W, Co, Al, Ni, Ru, Cu, TiN, and TaN is the third area.

The same approach can be applied to a case in which a fourth or more area exists.

As the upper limit value of the number of areas in which the materials differ, there is no particular limitation as long as the effect of the present invention is not impaired, but the upper limit value is, for example, 7 or less or 6 or less, and is typically 5 or less.

### Exposure

Examples of the method of exposing the surface of the substrate to the surface treatment agent include a method of exposing the surface of the substrate to the surface treatment agent by means of a coating method such as a dipping method, a spin coating method, a roll coating method, and a doctor blade method.

An exposure temperature is, for example, 10° C. or more and 90° C. or less, preferably 20° C. or more and 80° C. or less, more preferably 20° C. or more and 70° C. or less, and most preferably 20° C. or more and 30° C. or less.

From the viewpoint of selectively improving hydrophobicity between two or more adjacent areas which are made of different materials and which are formed on the substrate surface, an exposure time period is preferably 20 seconds or more, more preferably 30 seconds or more, and most preferably 45 seconds or more.

Although there is no particular limitation on the upper limit value of the above exposure time period, for example, the upper limit is 2 hours or less, typically 1 hour or less, preferably 15 minutes or less, more preferably 5 minutes or less, and particularly preferably 2 minutes or less.

Cleaning and/or drying may be performed as necessary after the above exposure.

Cleaning is performed, for example, by water rinsing, active agent rinsing, or the like. Drying is carried out by blowing nitrogen or the like. For example, as cleaning treatment by a cleaning liquid for a substrate surface including a patterned inorganic layer or a patterned organic layer, a cleaning liquid which has been conventionally used for cleaning treatment of a patterned inorganic layer or a patterned organic layer can be adopted as it is. Examples of the cleaning liquid include SPM (sulfuric acid and hydrogen peroxide solution), APM (ammonia and hydrogen peroxide solution), and the like with respect to the patterned inorganic layer, and water, active agent rinse, and the like with respect to the patterned organic layer. Further, a treated substrate after drying may be subjected to additional heating treatment of 100° C. or higher 300° C. or less, if necessary.

By the above exposure, the surface treatment agent can be selectively adsorbed on each area on the substrate surface, depending on the material of the area.

A contact angle with water of the substrate surface after exposure to the surface treatment agent may be, for example, 50° or more and 140° or less.

By controlling the material of the substrate surface, the type and the amount of the surface treatment agent to be used, and the exposure conditions and the like, the contact angle with water can be set to 50° or more, preferably 60° or more, more preferably 70° or more, and most preferably 90° or more.

Although there is no particular limitation on the upper limit value of the contact angle, the upper limit is, for example, 140° or less, and typically 130° or less.

In the surface treatment method, the materials are different between two or more adjacent areas on the substrate surface, therefore hydrophobicity can be selectively improved between two or more adjacent areas by the above exposure, and the contact angles with water can be made different from each other.

As the difference in contact angle with water between two or more adjacent areas, there is no particular limitation as long as the effect of the present invention is not impaired, and examples thereof include 10° or more. From the viewpoint of selectively improving hydrophobicity between two or more adjacent areas, the difference in the contact angle with water is preferably 20° or more, more preferably 30° or more, and most preferably 40° or more.

The upper limit value of the difference in contact angle is not particularly limited as long as the effect of the present invention is not impaired, and is, for example, 80° or less or 70° or less, and is typically 60° or less.

### Method for Selective Film Formation on Substrate

Subsequently, a method for selectively forming an area on a substrate using the above-described surface treatment method will be described. In this embodiment, the method for area-selectively forming a film on a substrate includes treating the surface of the substrate by the surface treatment method of the present invention, and forming a film on the surface of the substrate subjected to the surface treatment by an atomic layer deposition method (ALD method). By the method, a deposition amount of the material for the film is varied in an area-selective manner.

As a result of the above surface treatment, the contact angles with water differ between the two or more areas. In this case, preferably, the surface free energy differs between the above two or more areas. As a result, in this embodiment, it is possible to area-selectively differentiate, between the two or more areas, the deposition amount of the material for forming the film on the substrate surface.

Specifically, when comparing the contact angles with water between the two or more areas, in an area where the contact angle with water is larger than in the other area, the film forming material is less likely to be adsorbed in the area on the substrate surface by the ALD method, whereby a difference occurs in the deposition amount of the film forming material between the two or more areas. As a result, it is preferable that the deposition amount of the film forming material is area-selectively different on the substrate.

In the two or more areas, one area where the contact angle with water is larger than in the other area preferably has a lower surface free energy than the other area. Adsorption of the film forming material to the area is preferably chemisorption. Examples of the above chemisorption include chemisorption with a hydroxyl group and the like.

Examples of the area in which the contact angle with water tends to be larger than that in the other area between the two or more areas include an area containing at least one selected from the group consisting of W, Co, Al, Al₂O₃, Ni, Ru, Cu, TiN, and TaN. In the area where the contact angle with water tends to be larger than that in the other area, preferably, the surface free energy is lower.

Examples of the area in which the contact angle with water tends to be smaller than that in the other area between the two or more areas include an area containing at least one selected from the group consisting of Si, SiO₂, SiN, Ox, TiN, TaN, Ge, and SiGe. In the area where the contact angle with water tends to be smaller than that in the other area, preferably, the surface free energy is higher.

### Film Formation by ALD Method

Although there is no particular limitation on the film forming method by the ALD method, the film forming method is preferably a thin film forming method by adsorption using at least two gas phase reactants (hereinafter, simply referred to as “precursor gas”). Adsorption using a precursor gas is preferably chemisorption.

Specific examples thereof include a method in which the following steps (a) and (b) are repeated at least once (1 cycle) until a desired film thickness is obtained, and other methods:
(a) exposing a substrate surface treated by the method according to the second embodiment, to a pulse of a first precursor gas and
(b) subsequent to the step (a), exposing the substrate to a pulse of a second precursor gas.

After the step (a), before the step (b), the method may or may not include a plasma treatment step of removing or purging the first precursor gas and a reactant thereof by a carrier gas or the second precursor gas, or the like.

After the step (b), the method may or may not include a plasma treatment step of removing or purging the second precursor gas and a reactant thereof by a carrier gas or the like.

Examples of the carrier gas include an inert gas such as nitrogen gas, argon gas, helium gas, etc.

Each pulse in each cycle and each layer formed are preferably self-controlled, and more preferably each layer formed is a single atomic layer.

As the film thickness of the above monoatomic layer, for example, the thickness may be 5 nm or less, preferably 3 nm or less, more preferably 1 nm or less, and most preferably 0.5 nm or less.

Examples of the first precursor gas include an organometallic compound, a metal halide, metal oxohalide, and the like, and specifically include tantalum pentaethoxide, tetrakis(dimethylamino)titanium, pentakis(dimethylamino)tantalum, tetrakis(dimethylamino)zirconium, tetrakis(dimethylamino)hafnium, tetrakis(dimethylamino)silane, copper hexafluoroacetylacetonate vinyltrimethylsilane, Zn(C₂H₅)₂, Zn(CH₃)₂, TMA (trimethylaluminum), TaCl₅, WF₆, WOCl₄, CuCl, ZrCl₄, AlCl₃, TiCl₄, SiCl₄, HfCl₄, and the like.

Examples of the second precursor gas include a precursor gas capable of decomposing the first precursor or a precursor gas capable of removing the ligand of the first precursor, and specifically include H₂O, H₂O₂O₃, NH_{3,} H₂S, H₂Se, PH₃, ASH₃, C₂H₄, Si₂H₆, etc.

As an exposure temperature in the step (a), although there is no particular limitation, for example, the exposure temperature is 50° C. or more and 800° C. or less, preferably 100° C. or more and 650° C. or less, more preferably 125° C. or more and 500° C. or less, and most preferably 150° C. or more and 375° C. or less.

There is no particular limitation on the exposure temperature in step (b), and examples thereof include a temperature substantially equal to or higher than the exposure temperature in step (a).

The film formed by the ALD method is not particularly limited, but includes a film containing a pure element (e.g., Si, Cu, Ta, W), a film containing an oxide (e.g., SiO₂, GeO₂, HfO₂, ZrO₂, Ta₂O₅, TiO₂, Al₂O₃, Zno, SnO₂, Sb₂O₅, B₂O₃, In₂O₃, WO₃), a film containing a nitride (e.g., Si₃N₄, TiN, AlN, BN, GaN, NbN), a film containing a carbide (e.g., SiC), a film containing a sulfide (e.g., CdS, ZnS, MnS, WS₂, PbS), a film containing a selenide (e.g., CdSe, ZnSe), a film containing a phosphide (GaP, InP), a film containing an arsenide (e.g., GaAs, InAs), or a mixture thereof.

### EXAMPLES

Hereinafter, the present invention will be described more specifically based on the Examples and the Comparative Examples, but the present invention is not limited to the following Examples.

### Example 1 and Comparative Examples 1 to 2

### Preparation of Surface Treatment Agent

In the following solvent, the following compound (P) and the following compound (S) were uniformly mixed in the contents described in Table 1 below and the surface treatment agents of Example 1 and Comparative Examples 1 and 2 were prepared.

As the compound (P), the following P1 and P2 were used.
P1: Octadecylphosphonic acid
P2: Heptadecafluorodecylphosphonic acid

As the compound (S), the following S1 was used. S1: Heptanethiol

As the solvent, the following A1 was used. A1: Propylene glycol monomethyl ether

### Surface Treatment

Using the obtained surface treatment agents of Example 1 and Comparative Examples 1 to 2, surface treatment of copper substrates were performed according to the following method.

Specifically, pretreatment was performed by immersing the copper substrates in an aqueous HF solution having a concentration of 25 ppm for 10 seconds at 25° C. After the pretreatment, the copper substrates were washed with deionized water for 1 minute.

The copper substrates after washing with water were dried by a nitrogen gas stream. Each of the copper substrates after drying was immersed in each of the surface treatment agents described above for 1 minute at 25° C., to perform surface treatment of the copper substrates. The copper substrates after the surface treatment were washed with isopropanol for 1 minute, and then washed with deionized water for 1 minute. The washed copper substrates were dried by a nitrogen gas stream to obtain surface-treated copper substrates.

### Acid Immersion

The substrate after the HF pretreatment and each of the surface-treated copper substrates were immersed in an aqueous HCl solution having a concentration of 1.0% by mass for 1 minute at 25° C. After the acid immersion, the copper substrates were washed with deionized water for 1 minute. The copper substrates after washing with water were dried by a nitrogen gas stream.

### Base Immersion

The substrate after the HF pretreatment and each of the surface-treated copper substrates were immersed in an aqueous NH₃ solution having a concentration of 1.0% by mass for 1 minute at 25° C. After the base immersion, the copper substrates were washed with deionized water for 1 minute. The copper substrates after washing with water were dried by a nitrogen gas stream.

### Measurement of Contact Angles With Water

The contact angles with water of the substrate after the HF pretreatment, each of the substrates after the surface treatment, each of the substrates after the acid immersion, and each of the substrates after the base immersion were measured.

The contact angles with water were measured using Dropmaster 700 (manufactured by Kyowa Interface Science Co., Ltd.), as a contact angle at 2 seconds after dropping droplets (2.0 μL) of purified water on the surface of each substrate. Results are shown in Table 1.

### Decrease in Film Thickness of Copper Substrate

For each substrate after the acid immersion and each substrate after the base immersion, the amount of decrease in film thickness relative to each substrate before the immersion was measured.

A sheet resistance value was measured using a resistivity measuring instrument VR-250 (manufactured by Kokusai Electric Semiconductor Service Co., Ltd.). The film thickness was calculated from the sheet resistance value. Results are shown in Table 1.

TABLE 1

| | | ONLY HF | Comparative | Comparative | |
|---|---|---|---|---|---|
| | | PRETREATMENT | Example 1 | Example 2 | Example 1 |
| (Surface treatment agent) | | | | | |
| Compound(P) | Type/% by mass | — | P1/0.05 | P2/0.05 | P1/0.05 |
| Compound(S) | Type/% by mass | — | — | — | S1/0.5 |
| Solvent | Type | — | A1 | A1 | A1 |
| (Surface treatment) | | | | | |
| HF PRETREATMENT | | Yes | Yes | Yes | Yes |
| Surface treatment | | No | Yes | Yes | Yes |
| Water contact | After surface | 25.3 | 96.5 | 102.4 | 101.4 |
| angle (°) | treatment | | | | |
| | After acid | 17.1 | 50.3 | 102.6 | 103.2 |
| | immersion | | | | |
| | After base | 18.1 | 100.6 | 23 | 105.3 |
| | immersion | | | | |
| Decrease | After acid | 4.3 | 3.2 | 3.0 | 2.5 |
| amount in Cu | immersion | | | | |
| film thickness | After base | 5.3 | 5.6 | 5.5 | 5.2 |
| (nm) | immersion | | | | |

From Table 1, it can be seen that when the substrate was surface-treated with the surface treatment agent of Example 1, the water contact angles did not decrease even after the acid immersion or even after the base immersion, as compared with the cases in which the surface treatment agents of Comparative Examples 1 to 2 were used. From these results, it can be seen that the combined use of two types of SAM materials capable of forming self-assembled monolayers (SAMs) improves resistance to acids and bases.

### Example 2 and Comparative Examples 3 to 4

### Preparation of Surface Treatment Agent

In the following solvent, the following compound (P) and the following compound (S) were uniformly mixed in the contents described in Table 2 below and the surface treatment agents of Example 2 and Comparative Examples 3 and 4 were prepared.

As the compound (P), the following P1 was used.

### P1: Octadecylphosphonic Acid

As the compound (S), the following S2 and S-1 were used.

### S2: Octadecanethiol

### S-1: 1,2,3-benzotriazole

As the solvent, the following A2 was used. A2:1-octanol

### Surface Treatment, Acid Immersion, and Base Immersion

Using the obtained surface treatment agents of Example 2 and Comparative Examples 3 and 4, after pretreatment with an aqueous HF solution, surface treatment of copper substrates, acid immersion, and base immersion were performed in the same manner as in Example 1 and Comparative Examples 1 and 2, and the contact angles with water and the amount of decrease in film thickness of the copper substrates were measured. Results are shown in Table 2.

TABLE 2

| | | ONLY HF | Comparative | Comparative | |
|---|---|---|---|---|---|
| | | PRETREATMENT | Example 3 | Example 4 | Example 2 |
| (Surface treatment agent) | | | | | |
| Compound(P) | Type/% by mass | — | P1/0.05 | P1/0.05 | P1/0.05 |
| Compound(S) | Type/% by mass | — | — | S-1/0.5 | S2/0.5 |
| Solvent | Type | — | A2 | A2 | A2 |
| (Surface treatment) | | | | | |
| HF PRETREATMENT | | Yes | Yes | Yes | Yes |
| Surface treatment | | No | Yes | Yes | Yes |
| Water contact | After surface | — | 99.8 | 72.8 | 108.8 |
| angle (°) | treatment | | | | |
| | After acid | — | 92.8 | 38.5 | 108.5 |
| | immersion | | | | |
| | After base | — | 98.0 | 48.2 | 111.1 |
| | immersion | | | | |
| Decrease | After acid | 4.7 | 3.4 | 4.3 | 0.2 |
| amount in Cu | immersion | | | | |
| film thickness | After base | 4.9 | 4.4 | 4.3 | 4.1 |
| (nm) | immersion | | | | |

From the results of the decrease amounts in Cu film thickness of Table 2, it can be seen that, when the copper substrate was subjected to surface treatment using the surface treatment agent of Example 2 containing S2 as the compound (S), resistance against acid was remarkably improved as compared with a case in which the surface treatment agent of Comparative Example 4 containing S-1 used as an anticorrosive agent for copper was used in the same manner as in S2.

Further, from the results of the water contact angles of Table 2, it can be seen that when the substrate was subjected to surface treatment using the surface treatment agent of Example 2, the substrate was highly hydrophobized as compared with the case in which the surface treatment agent of Comparative Example 4 was used.

### Example 3

### Preparation of Surface Treatment Agent

To the following solvent, the following compound (P) and the following compound (S) were uniformly mixed in the contents described in Table 3 below and a surface treatment agent of Example 3 was prepared.

As the compound (P), the following P1 was used.

### P1: Octadecylphosphonic Acid

As the compound (S), the following S2 was used.

### S2: Octadecanethiol

As the solvent, the following A1 was used. A1: Propylene glycol monomethyl ether

### Surface Treatment, Acid Immersion, and Base Immersion

Using the obtained surface treatment agent of Example 3, after pretreatment with an aqueous HF solution, surface treatment of copper substrates, acid immersion, and base immersion were performed in the same manner as in Example 1 and Comparative Examples 1 and 2, and the contact angles with water and the amount of decrease in film thickness of the copper substrates were measured. The results are shown in Table 3 together with the results of Example 1 and Comparative Example 1.

TABLE 3

| | | Comparative | | |
|---|---|---|---|---|
| | | Example 1 | Example 1 | Example 3 |
| (Surface treatment agent) | | | | |
| Compound(P) | Type/% by mass | P1/0.05 | P1/0.05 | P1/0.05 |
| Compound(S) | Type/% by mass | — | S1/0.5 | S2/0.5 |
| Solvent | Type | A1 | A1 | A1 |
| (Surface treatment) | | | | |
| HF PRETREATMENT | | Yes | Yes | Yes |
| Surface treatment | | Yes | Yes | Yes |
| Water contact | After surface | 106.0 | 102.3 | 110.8 |
| angle (°) | treatment | | | |
| | After acid | 76.4 | 99.5 | 111.1 |
| | immersion | | | |
| | After base | 105.1 | 100.2 | 110.8 |
| | immersion | | | |
| Decrease | After acid | 3.1 | 2.7 | 0.1 |
| amount in Cu | immersion | | | |
| film thickness | After base | 5.9 | 6.2 | 2.5 |
| (nm) | immersion | | | |

From the results of decrease amounts in the Cu film thickness of Table 3, it can be seen that by increasing the number of carbon atoms of the compound (S), resistance against acid was improved.

### Examples 3 to 6 and Comparative Example 1

### Preparation of Surface Treatment Agent

In the following solvent, the following compound (P) and the following compound (S) were uniformly mixed in the contents described in Table 4 below and the surface treatment agents of Examples 3 to 6 and Comparative Example 1 were prepared.

As the compound (P), the following P1 was used.

### P1: Octadecylphosphonic Acid

As the compound (S), the following S2 was used.

### S2: Octadecanethiol

As the solvent, the following A1 was used.

### A1: Propylene Glycol Monomethyl Ether

### Surface Treatment, Acid Immersion, and Base Immersion

Using the obtained surface treatment agents of Examples 3 to 6 and Comparative Example 1, pretreatment with an aqueous HF solution, surface treatment of copper substrates, acid immersion, and base immersion were performed in the same manner as in Example 1 and Comparative Examples 1 and 2, and the contact angles with water and the amount of decrease in film thickness of the copper substrates were measured. Results are shown in Table 4.

TABLE 4

| | | Comparative | | | | |
|---|---|---|---|---|---|---|
| | | Example 1 | Example 4 | Example 3 | Example 5 | Example 6 |
| (Surface treatment agent) | | | | | | |
| Compound(P) | Type/% by mass | P1/0.05 | P1/0.05 | P1/0.05 | P1/0.05 | P1/0.05 |
| Compound(S) | Type/% by mass | — | S2/0.1 | S2/0.5 | S2/1.0 | S2/1.5 |
| Solvent | Type | A1 | A1 | A1 | A1 | A1 |
| (Surface treatment) | | | | | | |
| HF PRETREATMENT | | Yes | Yes | Yes | Yes | Yes |
| Surface treatment | | Yes | Yes | Yes | Yes | Yes |
| Water contact | After surface | 106 | 109.4 | 109.8 | 109.1 | 109.8 |
| angle (°) | treatment | | | | | |
| | After acid | 76.4 | 106.2 | 109.7 | 109.3 | 110.4 |
| | immersion | | | | | |
| | After base | 105.1 | 111.8 | 111.1 | 111.3 | 109.1 |
| | immersion | | | | | |
| Decrease | After acid | 2.3 | 2.8 | 0.8 | 0.6 | 0.1 |
| amount in Cu | immersion | | | | | |
| film thickness | After base | 8.5 | 4.5 | 1.6 | 1.8 | 0.0 |
| (nm) | immersion | | | | | |

From the results shown in Table 4, it can be seen that, with an increase in the concentration of the compound (S), the resistance against acid and base was improved even in terms of the water contact angle and in terms of the amount of decrease in Cu film thickness.

### Examples 2, 7 to 8 and Comparative Examples 3, 5

### Preparation of Surface Treatment Agents

In the following solvent, the following compound (P) and the following compound (S) were uniformly mixed in the contents described in Table 5 below, and the surface treatment agents of Examples 2, 7, and 8 and Comparative Examples 3 and 5 were prepared.

As the compound (P), the following P1 was used.

### P1: Octadecylphosphonic Acid

As the compound (S), the following S2 was used.

### S2: Octadecanethiol

As the solvent, the following A2 was used.

### A2: 1-Ocatanol

### Surface Treatment

Using the obtained surface treatment agents of Examples 2, 7, and 8 and Comparative Examples 3 and 5, after pretreatment with an aqueous HF solution, surface treatment of copper substrates was performed in the same manner as in Example 1 and Comparative Examples 1 and 2.

### Heat Treatment

The above surface-treated copper substrates were subjected to heat treatment for 20 minutes at 200° C.

### Measurement of Contact Angle With Water

The contact angle with water of each substrate was measured before and after the above heat treatment. Results are shown in Table 5.

### Measurement of Surface Coverage Rate on the Substrate

With respect to each substrate before the heat treatment, the surface coverage rate by the surface treatment agent relative to the copper substrate was calculated by cyclic voltammetry. Results are shown in Table 5.

TABLE 5

| | | Comparative | | | | Comparative |
|---|---|---|---|---|---|---|
| | | Example 3 | Example 7 | Example 8 | Example 2 | Example 5 |
| (Surface treatment agent) | | | | | | |
| Compound(P) | Type/% by mass | P1/0.05 | P1/0.05 | P1/0.05 | P1/0.05 | — |
| Compound(S) | Type/% by mass | — | S2/0.005 | S2/0.05 | S2/0.5 | S2/0.5 |
| Solvent | Type | A2 | A2 | A2 | A2 | A2 |
| (Surface treatment) | | | | | | |
| HF PRETREATMENT | | Yes | Yes | Yes | Yes | Yes |
| Surface treatment | | Yes | Yes | Yes | Yes | Yes |
| Water contact | Before heat | 92.7 | 97.6 | 108.8 | 109.4 | 108.6 |
| angle (°) | treatment | | | | | |
| | After heat | 90.2 | 94.3 | 92.9 | 85.9 | 53.6 |
| | treatment | | | | | |

| | | | | | |
|---|---|---|---|---|---|
| Surface coverage rate (%) | 36.5 | 49.9 | 87.2 | 95.4 | 98.4 |

From the results shown in Table 5, it can be seen that, when the substrate was subjected to surface treatment with the surface treatment agent of Comparative Example 5 in which only the compound (S) was blended, the surface coverage was high, but the water contact angle after the heat treatment significantly decreased as compared with the contact angle before the heat treatment, and thus the substrate could not withstand the actual process temperature. In addition, it can be seen that when the substrate was surface-treated with the surface treatment agent of Comparative Example 3 in which only the Compound (P) was blended, the heat resistance was high, but the surface coverage was low and the resistance against acid and base was incomplete. On the other hand, it can be seen that when the surface treatment was performed with the surface treatment agents of Examples 2, 7, and 8 in which the compound (S) and the compound (P) were used in combination, both the surface coverage and the heat resistance were excellent.

### Examples 2 to 3 and Comparative Example 3

### Surface Treatment Using SiO₂ Substrate

Surface treatment of a SiO₂ substrate was performed using the surface treatment agents of Examples 2 to 3 and Comparative Example 3 after pretreatment with an aqueous HF solution in the same manner as in Example 1 and Comparative Examples 1 and 2, except that the SiO₂ substrate was used instead of the copper substrate. Then, the contact angles with water were measured. The results are shown in Table 6, together with the results obtained when copper substrates were used.

TABLE 6

| | | Comparative | | |
|---|---|---|---|---|
| | | Example 3 | Example 2 | Example 3 |
| (Surface treatment agent) | | | | |
| Compound(P) | Type/% by mass | P1/0.05 | P1/0.05 | P1/0.05 |
| Compound(S) | Type/% by mass | — | S2/0.5 | S2/0.5 |
| Solvent | Type | A2 | A2 | A1 |
| (Surface treatment) | | | | |
| HF PRETREATMENT | | Yes | Yes | Yes |
| Surface treatment | | Yes | Yes | Yes |
| Water contact | Cu | 107.4 | 114.0 | 114.5 |
| angle (°) | SiO₂ | 32.8 | 45.7 | 34.5 |

From the results shown in Table 6, it can be seen that, the copper substrate also could be selectively hydrophobized as compared with the SiO₂ substrate when the surface treatment agents of Examples 2 and 3, which contain a combination of the compound (P) and the compound (S), were used, similarly to when the surface treatment agent of Comparative Example 3 containing only the compound (P) was used.

What is claimed is:

1. A method for surface treating a surface of a substrate, the method comprising:
exposing the surface to a surface treatment agent,
wherein the surface treatment agent comprises:
a compound (P) represented by the following general formula (P-1):
R¹—P(═O)(OR²)(OR³) (P-1)
wherein R¹ is an alkyl group, an alkoxy group, a fluorinated alkyl group, or an aromatic hydrocarbon group which may have a substituent, and R² and R³ are each independently a hydrogen atom, an alkyl group, a fluorinated alkyl group, or an aromatic hydrocarbon group which may have a substituent;
a compound (S) represented by the following formula (S-1):
R—SH (S-1)
wherein R is an alkyl group having 3 or more carbon atoms, a fluorinated alkyl group having 3 or more carbon atoms, or an aromatic hydrocarbon group which may have a substituent; and
a solvent,
wherein the surface comprises two or more areas wherein materials of adjacent areas are different from each other; and
the adjacent areas in the two or more areas have different contact angles due to reaction of the compound (P) and the compound (S) with the two or more areas.

2. The method for surface treating a surface of a substrate according to claim 1, wherein at least one area of the two or more areas has a surface made of a metal.

3. The method for surface treating a surface of a substrate according to claim 1, wherein the metal is copper, cobalt, or ruthenium.

4. The method for surface treating a surface of a substrate according to claim 1, wherein in the formula (P-1), R¹ is an alkyl group having 8 or more carbon atoms, an alkoxy group having 8 or more carbon atoms, a fluorinated alkyl group having 8 or more carbon atoms, or an aromatic hydrocarbon group which may have a substituent, and R² and R³ are each independently a hydrogen atom, an alkyl group having 8 or more carbon atoms, a fluorinated alkyl group having 8 or more carbon atoms, or an aromatic hydrocarbon group which may have a substituent.

5. The method for surface treating a surface of a substrate according to claim 1, wherein, in the formula (S-1), R is a linear or branched alkyl group or a linear or branched fluorinated alkyl group, and the alkyl group or the fluorinated alkyl group has 7 or more carbon atoms.

6. The method for surface treating a surface of a substrate according to claim 1, wherein a content of the compound (S) is 0.05% by mass or more and 5% by mass or less, with respect to the total mass of the surface treatment agent.

7. The method for surface treating a surface of a substrate according to claim 1, wherein A content of the compound (P) is 0.001% by mass or more and 5% by mass or less, with respect to the total mass of the surface treatment agent.
